(19) United States
(12) Patent Application Publication
(10) Pub. No.: US 2018/0301532 A1
(43) Pub. Date: Oct. 18, 2018

(54) THIN FILM TRANNSISTOR

(71) Applicant: Wuhan China Star Optoelectronics Technology Co., Ltd., Wuhan, Hubei (CN)

(72) Inventors: Yuebai Han, Wuhan, Hubei (CN); Xiaojiang Yu, Wuhan, Hubei (CN)

(73) Assignee: Wuhan China Star Optoelectronics Technology Co., L td., Wuhan, Hubei (CN)

(21) Appl. No.: 15/522,841

(22) PCT Filed: Mar. 9, 2017
(86) PCT No.: PCT/CN2017/076083

§ 371 Date: Oct. 3, 2017

(30) Foreign Application Priority Data
Feb. 22, 2017 (CN) 201710096247.1

(51) Int. Cl. H01L 29/06; H01L 29/66; H01L 29/786

(52) U.S. Cl. CPC H01L 29/0684; H01L 29/786; H01L 29/6675; H01L 29/0603

(57) ABSTRACT

Disclosed is a thin film transistor, which includes a shading layer and a poly-silicon layer, the shading layer being arranged below the poly-silicon layer. when viewed from a top perspective, the shading layer and the poly-silicon layer have an angle therebetween, the angle being an acute angle or an obtuse angle. The thin film transistor breaks processing constrains and makes it possible to reduce the inclination degree of the poly-silicon layer at an edge of a sloping part of the shading layer in a larger range, thereby improving the conductivity of the poly-silicon layer.

### CROSS-REFERENCE TO RELATED APPLICATIONS

This application claims the priority of Chinese patent application CN201710096247.1, entitled “Thin film transistor” and filed on Feb. 22, 2017, the entirety of which is incorporated herein by reference.

### FIELD OF THE INVENTION

The present disclosure relates to the technical field of thin film transistors, and in particular, to a shading layer of a low-temperature poly-silicon panel.

### BACKGROUND OF THE INVENTION

Low-temperature poly-silicon (LTPS) panels have advantages such as high resolution, high mobility, and low power consumption, and have been widely used in products with flat display panels like cell phones (e.g., iphone, Samsung, Huawei, MI, Meizu, etc.) and tablet PCs.

However, the process for manufacturing an LTPS component is very complex, and at present an LTPS component mostly adopts a top-gate structure, which means a metal film has to be formed first on a glass to serve as a shading layer. Because a poly-silicon layer forms an inclination angle (i.e., slope) at an edge of a sloping part of the shading layer, the poly-silicon layer is likely to be damaged during excimer laser annealing (ELA). Electrical properties of the poly-silicon layer thus may be affected. That is to say, too large inclination angle of the sloping part of the shading layer may cause an abnormal conductivity of the poly-silicon layer at the edge of the sloping part of the shading layer. By reducing the inclination angle at the edge of the sloping part of the shading layer, it is possible to remarkably improve the conductive properties of the poly-silicon layer at the edge of the sloping part of the shading layer, thereby reducing, for example, bright or dark spots and the like. However, due to constraints of equipments and process capacities, it is not possible to reduce the inclination angle at the edge of the sloping part of shading layer to a greater extent.

Chinese patent application number CN201410837376.8 provides a technical solution for arranging a shading layer in a low-temperature poly-silicon thin film transistor, but it fails to provide a technical solution for improving the conductive properties of an active layer (i.e., a poly-silicon layer).

Therefore, it is desirable to provide a new thin film transistor, so that the inclination angle of the poly-silicon layer at the edge of the sloping part of the shading layer can be reduced, thereby improving the conductivity of the poly-silicon layer.

### SUMMARY OF THE INVENTION

In view of the above problems, the present disclosure proposes a new shading layer pattern which can improve the inclination angle at the edge of the shading layer more efficiently by breaking constraints of equipments and process capacities, thereby improving the conductive properties of the poly-silicon layer and improving production yield.

The present disclosure provides a thin film transistor, comprising a shading layer and a poly-silicon layer, the shading layer being arranged below the poly-silicon layer.

When viewed from a top perspective, the shading layer and the poly-silicon layer have an angle therebetween, the angle being an acute angle or an obtuse angle.

In a plan view, an edge of the poly-silicon layer parallel to a growth direction of the poly-silicon layer is set as a first side, and an edge of the shading layer in contact with the poly-silicon layer is set as a second side.

The angle is an intersection angle between the first side and the second side.

The second side is in a shape of sawteeth.

When viewed from a top perspective view, the shading layer is in a shape of a trapezoid.

A leg of the trapezoid serves as the second side, and bases of the trapezoid are parallel to the first side.

When viewed from a top perspective view, the shading layer is in a shape of a parallelogram.

One side of the parallelogram serves as the second side, and another side of the parallelogram intersecting the second side is parallel to the first side.

The shading layer is a metal film.

In the present disclosure, the edge of the shading layer is designed to have a sawteeth shape, or the shading layer is directly designed to have a shape of a trapezoid or a parallelogram when viewed from a top perspective, so that the poly-silicon layer and the shading layer are not perpendicularly arranged to each other, but with a certain angle (an acute or an obtuse angle) therebetween, thereby reducing the inclination degree of the poly-silicon layer with respect to the shading layer at the edge of the sloping part and improving the conductivity of the poly-silicon layer thereof.

The technical features described above may be combined in various suitable ways or may be replaced by equivalent technical features, provided that the objective of the present disclosure is achieved.

### BRIEF DESCRIPTION OF THE DRAWINGS

The present disclosure will be described in a more detailed way below based on embodiments and with reference to the accompanying drawings, in which:

FIG. 1 is a perspective view showing a positional relationship between a poly-silicon layer and a shading layer in the prior art;

FIG. 2 is a schematic view showing a structure when the poly-silicon layer is perpendicular to the shading layer in the prior art;

FIG. 3 is a perspective view showing a positional relationship between the poly-silicon layer and the shading layer in the present disclosure;

FIG. 4 is a schematic view showing a structure in which an edge of the shading layer is in a shape of sawteeth when viewed from a top perspective in the present invention;

FIG. 5 is a schematic view showing a structure when the shading layer is in a shape of a trapezoid when viewed from a top perspective in the present invention;

FIG. 6 is a schematic view showing a structure when the shading layer is in a shape of a parallelogram when viewed from a top perspective in the present invention;

1—shading layer;
2—poly-silicon layer;
3—gate;
4—source.

In the accompanying drawings, same components use same reference signs. The accompanying drawings are not drawn according to actual proportions.

### DETAILED DESCRIPTION OF THE EMBODIMENTS

The present disclosure will be further described below in combination the accompanying drawings.

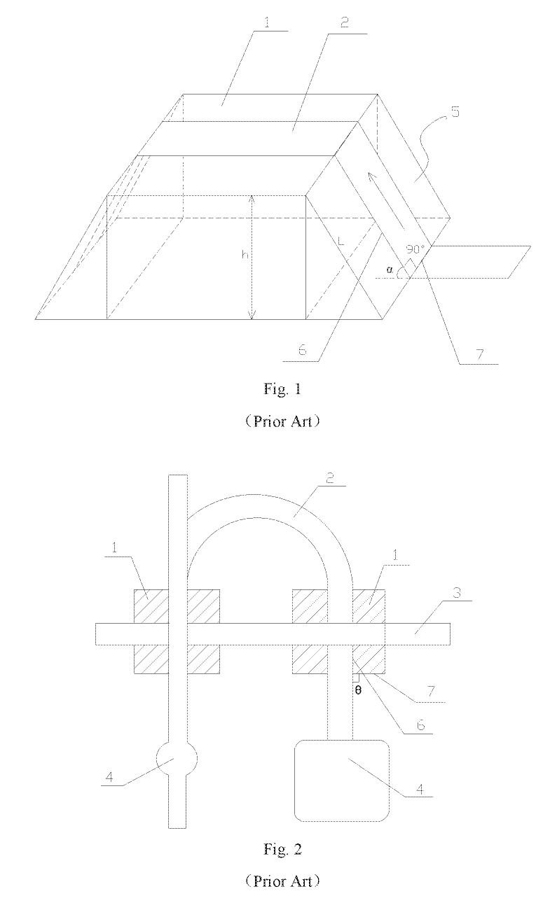

Referring to FIGS. 1 and 3, the arrow indicated on a poly-silicon layer 2 indicates a growth direction of the poly-silicon layer 2 (also referred to as an extension direction of the poly-silicon layer 2). In the present invention, an edge of the poly-silicon layer parallel to the growth direction of the poly-silicon layer 2 is referred to as a first side 6, and an edge of the shading layer 1 in contact with the poly-silicon layer 2 is referred to as a second side 7.

Referring to the top view in FIG. 2, in the prior art, the poly-silicon layer 2 is perpendicular to the shading layer 1, that is, an angle θ between the first side 6 and the second side 7 is 90°. As can be seen from FIG. 1, an inclination angle of a sloping part 5 of the shading layer is a which herein can be understood as a slope angle of the sloping part 5 of the shading layer 1 at an edge thereof in a front view. L is a sloping length of the poly-silicon layer 2 along its growth direction, and h is a thickness of the shading layer 1. In the prior art, the trigonometric function relationship among the inclination angle α of the poly-silicon layer 2 at the sloping part 5, L, and h can be expressed as sin(α)=h/L, that is, the inclination angle α=arcsin(h/L). In this case, the inclination angle is too large, which may easily cause damage to the poly-silicon layer 2 during excimer laser annealing, thus resulting in an abnormal conductivity of the poly-silicon 2 layer at the edge of the sloping part 5 of the shading layer.

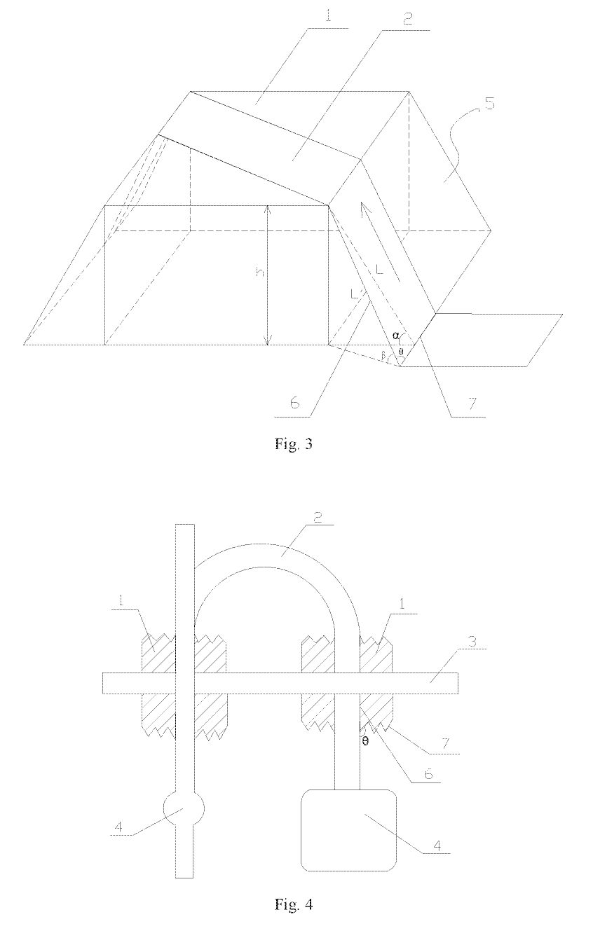

The present disclosure is to solve the problems in the prior art described above, and provides a thin film transistor comprising a shading layer 1 and a poly-silicon layer 2, the shading layer I being arranged below the poly-silicon layer 2. Viewed from a top perspective, the shading layer 1 and the poly-silicon layer 2 form an angle θ therebetween, the angle θ being an acute angle or an obtuse angle. The present disclosure does not adopt the technical solution of the prior art in which the shading layer 1 and the poly-silicon layer 2 are arranged perpendicular to each other, but a solution in which the angle θ is an acute angle or an obtuse angle when viewed from a top perspective, i.e., in FIG. 3, the intersection angle θ of the first side 6 and the second side 7 is an acute angle or an obtuse angle. As shown in FIG. 4, in a preferred embodiment, the second side 7, which intersects the first side 6, is in the shape of sawteeth.

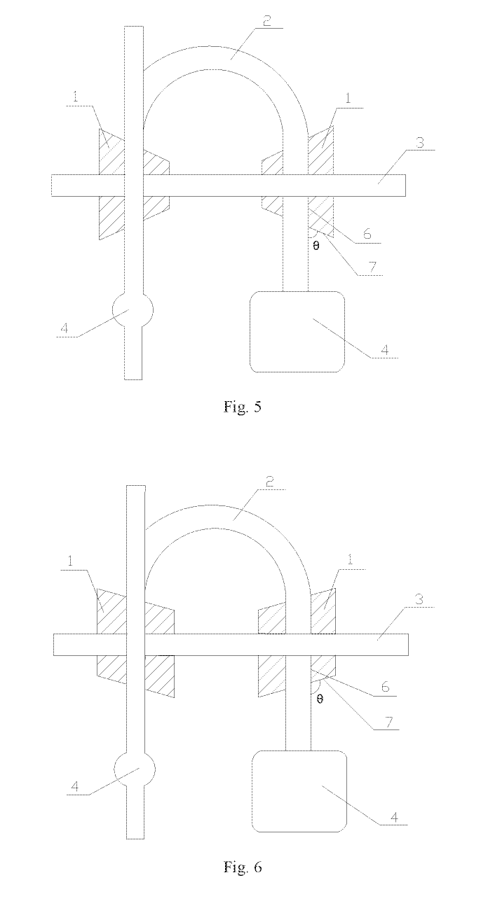

As shown in FIG. 5, in a preferred embodiment, the shading layer 1 is in the shape of a trapezoid when viewed from a top perspective. A leg of the trapezoid is the second side, and bases thereof are parallel to the first side.

As shown in FIG. 6, in a preferred embodiment, the shading layer 1 is in the shape of a parallelogram when viewed from a top perspective. One side of the parallelogram is the second side and another side of the parallelogram intersecting the second side is parallel to the first side.

Referring to FIGS. 4, 5, and 6, according to the technical solutions of the present disclosure, designing the second side of the shading layer 1 perpendicular to the poly-silicon layer 2 to have the shape of sawteeth when viewed from a top perspective and designing the shading layer 1 to have the shape of a trapezoid or a parallelogram are for the same main purpose that the angle θ formed between the poly-silicon layer 2 and the shading layer 1 is an acute angle or an obtuse angle, not equal to 90°. The principle for designing the angle θ is as follows.

As shown in FIG. 3, compared with the prior art, an equivalent sloping length of the poly-silicon layer 2 along its growth direction can be expressed as L′=L/sin(θ), i.e., a length of the first side 6 is L′, and an equivalent inclination angle is β. The trigonometric function relationship among β, L′, and h can be expressed as sin(β)=h/L′=sin(θ)×h/L <sin(α), i.e., sin(β)=sin(α)×sin(θ), and the equivalent inclination angle β=arcsin(sin(α)×sin(θ)). Therefore, when the shading layer 1 and the poly-silicon layer 2 are not perpendicular to each other (i.e., the angle θ is an acute angle or an obtuse angle) when viewed from a top perspective, the equivalent inclination angle β is smaller than the inclination angle α in the prior art. In this way, the inclination degree of the poly-silicon layer 2 at the edge of the sloping part 5 of the shading layer 1 can be reduced. The conductivity of the poly-silicon layer 2 at the edge of the sloping part 5 is thus improved.

In a preferred embodiment, the shading layer 1 is a metal film.

The present disclosure breaks processing constrains through the proper design of the shape of the shading layer 1. The inclination degree of the poly-silicon layer 2 with respect to the shading layer 1 is adjusted through changing the size of the angle θ, by means of which it is possible to reduce the inclination degree of the poly-silicon layer 2 at the edge of the sloping part 5 of the shading layer 1 in a larger range, thereby improving the conductivity of the poly-silicon layer 2.

While the present disclosure has been described with reference to preferred embodiments, various modifications may be made thereto without departing from the scope of the disclosure, and equivalents may be substituted for pails thereof. In particular, the technical features mentioned in the various embodiments may be combined in any manner as long as there is no structural conflict. The present disclosure is not limited to the specific embodiments disclosed herein, but includes all technical solutions falling within the scope of the claims.

1. A thin film transistor, comprising a shading layer and a poly-silicon layer, wherein:
the shading layer is arranged below the poly-silicon layer; and
when viewed from a top perspective, the shading layer and the poly-silicon layer have an angle therebetween, the angle being an acute angle or an obtuse angle.

2. The thin film transistor according to claim 1, wherein:
in a top view, an edge of the poly-silicon layer parallel to a growth direction of the poly-silicon layer is set as a first side, and an edge of the shading layer in contact with the poly-silicon layer is set as a second side; and
the angle is an intersection angle between the first side and the second side.

3. The thin film transistor according to claim 2, wherein the shading layer is a metal film.

4. The thin film transistor according to claim 2, wherein the second side is in a shape of sawteeth.

5. The thin film transistor according to claim 4, wherein the shading layer is a metal film.

6. The thin film transistor according to claim 2, wherein the shading layer is in a shape of a trapezoid when viewed from a top perspective.

7. The thin film transistor according to claim 6, wherein the shading layer is a metal film.

8. The thin film transistor according to claim 6, wherein a leg of the trapezoid serves as the second side, and bases of the trapezoid are parallel to the first side.

9. The thin film transistor according to claim 2, wherein the shading layer is in a shape of a parallelogram when viewed from a top perspective.

10. The thin film transistor according to claim 9, wherein the shading layer is a metal film.

11. The thin film transistor according to claim 9, wherein one side of the parallelogram serves as the second side, and another side of the parallelogram intersecting the second side is parallel to the first side.

12. The thin film transistor according to claim 1, wherein the shading layer is a metal film.

13. The thin film transistor according to claim 7, wherein a lea of the trapezoid serves as the second side, and bases of the trapezoid are parallel to the first side.

14. The thin film transistor according to claim 10, wherein one side of the parallelogram serves as the second side, and another side of the parallelogram intersecting the second side is parallel to the first side.
